(19) United States
(12) Patent Application Publication
(10) Pub. No.: US 2025/0380576 A1
(43) Pub. Date: Dec. 11, 2025

(54) PIXEL DEFINE LAYER OPENING FOR OLED MODULE FABRICATION

(71) Applicant: Applied Materials, Inc., Santa Clara, CA (US)

(72) Inventors: Yu-Hsin LIN, Zhubei City (TW); Chung-chia CHEN, Hsinchu City (TW); Ji Young CHOUNG, Hwaseong-si (KR); Sheng-Wen WANG, Tainan City (TW)

(21) Appl. No.: 19/225,087

(22) Filed: Jun. 2, 2025

Related U.S. Application Data
(60) Provisional application No. 63/656,941, filed on Jun. 6, 2024.

(51) Int. Cl. H10K 59/122; H10K 59/12; H10K 59/80

(52) U.S. Cl. CPC H10K 59/122; H10K 59/1201; H10K 59/80515

(57) ABSTRACT

Embodiments of the disclosure include apparatus and methods for organic light-emitting diode (OLED) module fabrication. A plurality of recesses are formed in a pixel define layer that is formed over a surface of a substrate. The plurality of recesses in the pixel define layer are each disposed over an anode region formed in the surface of the substrate. A blanket layer of material is deposited over the pixel define layer. A first portion of the blanket layer of material disposed over a first recess of the plurality of recesses is removed to expose a first portion of the pixel define layer and form a first overhang portion above the first recess. The first portion of the pixel define layer is removed using the first overhang portion as a mask to expose at least a portion of a first anode region.

### CROSS-REFERENCE TO RELATED APPLICATIONS

This application claims priority to U.S. Provisional Patent Application Ser. No. No. 63/656,941, filed Jun. 6, 2024, which is herein incorporated by reference.

### BACKGROUND

### Field

Embodiments described herein generally relate to organic light-emitting diode (OLED) module fabrication process sequences.

### Description of the Related Art

An organic light-emitting diode (OLED) module is fabricated in layers on a substrate by performing operations including depositing and patterning of materials. Generally, a deposition process adds materials/layers to an assembly and a patterning forms functional structures in the deposited materials/layers. The fabrication process also involves the use of or the formation of various masks which cover some portions of the assembly and leave other portions of the assembly exposed. The masks are often used for preventing a material from being deposited onto a portion of a structure or for preventing a patterning process from damaging the portion of the structure. Each of the independent operations (e.g., depositing, patterning, masking, etc.) that are performed to fabricate the OLED module increases overall fabrication time. Increasing overall fabrication time reduces manufacturing throughput and generally increases fabrication costs.

Accordingly, there is a need in the art for a desirable technique that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide a method that includes forming a plurality of recesses in a pixel define layer formed over a surface of a substrate. The plurality of recesses in the pixel define layer are each disposed over an anode region formed in the surface of the substrate. A blanket layer of material is deposited over the pixel define layer. A first portion of the blanket layer of material disposed over a first recess of the plurality of recesses is removed to expose a first portion of the pixel define layer and form a first overhang portion above the first recess. The first portion of the pixel define layer is removed using the first overhang portion as a mask to expose at least a portion of a first anode region.

Embodiments of the present disclosure provide a method that includes forming a plurality of recesses in a pixel define layer formed over a surface of a substrate. The plurality of recesses in the pixel define layer are each disposed over an anode region formed in the surface of the substrate. A first layer of material is deposited over the pixel define layer and a second layer of material is deposited over the first layer of material. A first portion of the first layer of material disposed over a first recess of the plurality of recesses and a first portion of the second layer of material disposed over the first recess are removed to expose a first portion of the pixel define layer and form a first overhang portion above the first recess. The first portion of the pixel define layer is removed using the first overhang portion as a mask to expose at least a portion of a first anode region.

Embodiments of the present disclosure provide a device subassembly that includes a substrate having a surface. A plurality of anode regions are disposed on the surface of the substrate. A pixel define layer is disposed over the surface of the substrate. The pixel define layer includes a plurality of openings and each opening of the openings in the pixel define layer is formed over an anode region of the anode regions. A first layer of material and a second layer of material are disposed over the pixel define layer. Openings are formed in the first layer of material and the second layer of material. The openings in the first layer of material and the second layer of material are formed over and surround the openings in the pixel define layer.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic cross-sectional view of an anode, in accordance with certain embodiments of the present disclosure.

FIG. 1B is a schematic cross-sectional view of a pixel define layer and a halftone mask, in accordance with certain embodiments of the present disclosure.

FIG. 2 is a schematic cross-sectional view of a plurality of recesses formed in a pixel define layer, in accordance with certain embodiments of the present disclosure.

FIG. 3 is a schematic cross-sectional view of a first layer of material deposited over a pixel define layer and a second layer of material deposited over the first layer of material, in accordance with certain embodiments of the present disclosure.

FIG. 4 is a schematic cross-sectional view of masking a first layer of material and a second layer of material using a mask with an opening over a first portion of the first layer of material and a first portion of the second layer of material, in accordance with certain embodiments of the present disclosure.

FIG. 5 is a schematic cross-sectional view of removing a first portion of a first layer of material and a first portion of a second layer of material to expose a first portion of a pixel define layer and form a first overhang portion over a first recess in the pixel define layer, in accordance with certain embodiments of the present disclosure.

FIG. 6 is a schematic cross-sectional view of removing a first portion of a pixel define layer using a first overhang portion as a mask to expose at least a portion of a first anode region, in accordance with certain embodiments of the present disclosure.

FIG. 7 is a schematic cross-sectional view of emissive layer material deposited over a portion of a first anode and a layer of material, in accordance with certain embodiments of the present disclosure.

FIG. 8 is a schematic cross-sectional view of thin-film encapsulation material deposited over emissive layer material, in accordance with certain embodiments of the present disclosure.

FIG. 9 is a schematic cross-sectional view of masking a first overhang portion, in accordance with certain embodiments of the present disclosure.

FIG. 10 is a schematic cross-sectional view of removed thin-film encapsulation material and emissive layer material, in accordance with certain embodiments of the present disclosure.

FIG. 11 is a schematic cross-sectional view of masking a first layer of material and a second layer of material using a mask with an opening over a second portion of the first layer of material and a second portion of the second layer of material, in accordance with certain embodiments of the present disclosure.

FIG. 12 is a process flow diagram illustrating a method for forming a portion of an OLED module, in accordance with certain embodiments of the present disclosure.

FIG. 13 is a schematic cross-sectional view of an OLED module assembly, in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to apparatus and methods for organic light-emitting diode (OLED) module fabrication. More specifically, embodiments of the present disclosure relate to a pixel define layer opening for OLED module fabrication. In some embodiments, a pixel define layer is disposed over a substrate and anodes are disposed in anode regions formed in a surface of the substrate. In one or more embodiments, a halftone mask directs light from a light source to form active regions in a photoresist material disposed over a surface of the pixel define layer.

In various embodiments, the active regions are disposed over the anode regions formed in the surface of the substrate, and the active regions are removed using a developer. After removing the active regions, portions of the surface of the pixel define layer below the active regions are exposed. A material removal process is performed to form a plurality of recesses in the pixel define layer such that each recess of the plurality of recesses is disposed over an anode region of the anode regions.

In some embodiments, a blanket layer of material is deposited over the pixel define layer. In one or more embodiments, the blanket layer of material includes multiple layers of materials. In various embodiments, a portion of the blanket layer of material disposed over a recess of the plurality of recesses is removed using an etching process to expose a portion of the pixel define layer and form an overhang portion above the recess.

In certain embodiments, the portion of the pixel define layer is removed using the overhang portion as a mask to expose a portion of an anode region. Without the portion of the pixel define layer, an anode disposed in the anode region could be damaged during the etching process that forms the overhang portion which would require an additional operation. By forming the plurality of recesses in the pixel define layer using the halftone mask, the additional operation is avoided and the anode is not damaged by the etching process.

### Pixel Define Layer Opening Examples

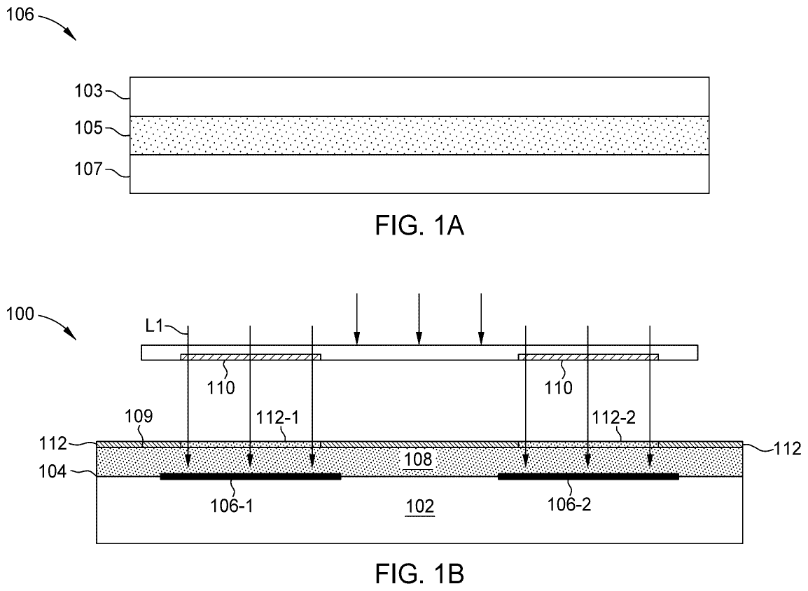

FIG. 1A is a schematic cross-sectional view of an anode 106. In some embodiments, the anode 106 includes a first layer 103, a second layer 105, and a third layer 107. The first layer 103 may include a transparent conductive oxide (TCO) such as indium zinc oxide (IZO), indium tin oxide (ITO), or another TCO. In some examples, the second layer 105 includes a reflective electrically conductive material such as a reflective silver. In various embodiments, the third layer 107 includes a TCO such as IZO, ITO, or another TCO.

FIG. 1B is a schematic cross-sectional view 100 of a pixel define layer 108 and a halftone mask 110. The view 100 includes a substrate 102 having a surface 104. In one or more embodiments, the substrate 102 can include an indium tin oxide (ITO) layer formed on a glass substrate. In certain embodiments, the substrate 102 includes a thin-film transistor (TFT) backplane that includes the surface 104. In some embodiments, a first anode 106-1 is disposed in a first anode region formed as part of the surface 104 and a second anode 106-2 is disposed in a second anode region formed as part of the surface 104. In various embodiments, the first and second anode regions are pre-patterned in the surface 104 and the first and second anodes 106-1, 106-2 include an electrically conductive material such as chromium, titanium, gold, silver, copper, aluminum, etc.

The pixel define layer 108 is disposed over the surface 104 of the substrate 102 and over the first and second anodes 106-1, 106-2. In some embodiments, the pixel define layer 108 includes an organic material such as polyimide, an inorganic material, or an organic material with an inorganic coating. In one or more embodiments, a layer 112 of a photosensitive material, such as a photoresist material is deposited on or coated over a surface 109 of the pixel define layer 108. In some embodiments, the halftone mask 110 includes transparent regions and opaque regions formed therein. In various embodiments, the halftone mask 110 includes a halftone phase shift mask.

The halftone mask 110 and the surface 109 of the pixel define layer 108 are exposed to light from a light source (not shown) such as an ultraviolent light source positioned over the halftone mask 110. The light L1 from the light source is transmitted through the transparent regions of the halftone mask 110 and the transmitted light forms exposed portions 112-1, 112-2 in the layer 112 of the light sensitive material, which for ease of discussion is referred to as a photoresist mask below. The halftone mask 110 and the transmitted light L1 also form an additional exposed portion over a via (not shown) In various embodiments, the exposed portions 112-1, 112-2 of the layer 112 are removed using a developer such as an alkaline developer, a semi-aqueous developer, etc.

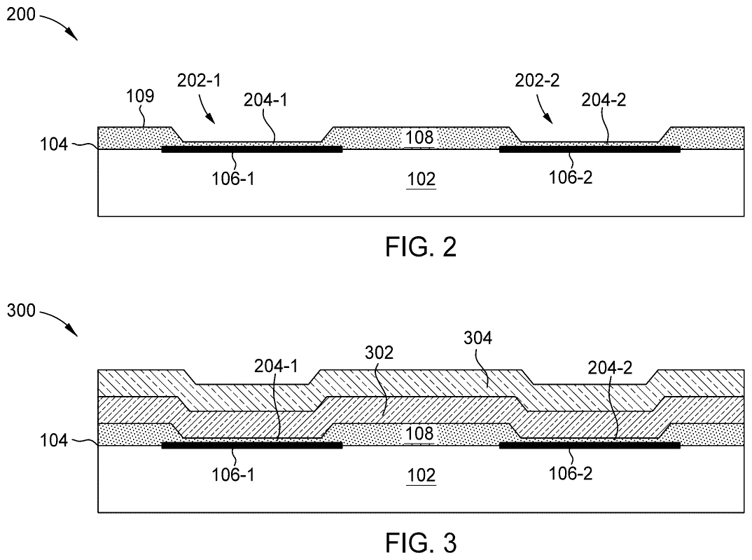

FIG. 2 is a schematic cross-sectional view 200 of a plurality of recesses formed in a pixel define layer 108. In the illustrated example, the material removal process has formed a plurality of recesses in the surface 109 of the pixel define layer 108 which include a first recess 202-1 and a second recess 202-2. In various embodiments, the remaining photoresist material used as the photoresist mask is removed/stripped by solvents/chemicals. As shown, the first recess 202-1 is formed over the first anode region and a portion of the first anode 106-1. Similarly, the second recess 202-2 is formed over the second anode region and a portion of the second anode 106-2. The entire thickness of the pixel define layer 108 is removed based on the additional exposed portion to open the via (not shown), but the first portion 204-1 is not removed in order to protect the first anode 106-1 during an etching process.

In various embodiments, the material removal process does not remove all of the pixel define layer 108 disposed between the surface 109 and the first anode 106-1 such that a first portion 204-1 of the pixel define layer 108 covers the first anode 106-1. In one or more embodiments, the material removal process also does not remove all of the pixel define layer 108 disposed between the surface 109 and the second anode 106-2 and a second portion 204-2 of the pixel define layer 108 covers the second anode 106-2. In some embodiments, the first and second portions 204-1, 204-2 of the pixel define layer 108 are configured to prevent the first and second anodes 106-1, 106-2, respectively, from being damaged during a subsequent etching process.

FIG. 3 is a schematic cross-sectional view 300 of a first layer of material 302 deposited over a pixel define layer 108 and a second layer of material 304 deposited over the first layer of material 302. In some embodiments, the first layer of material 302 and the second layer of material 304 are each deposited as blanket layers of materials (e.g., a single layer). Although two layers of material are described, it is to be appreciated, that in some embodiments, more than two layers of material can be deposited over the pixel define layer 108. In various embodiments, the first layer of material 302 is deposited over the pixel define layer 108 and the second layer of material 304 is deposited over the first layer of material 302 using thermal evaporation (thermal deposition), chemical vapor deposition (CVD), plasma enhanced chemical vapor deposition (PECVD), physical vapor deposition (PVD), etc.

In one or more embodiments, the first layer of material 302 includes aluminum, molybdenum, copper, indium zinc oxide, indium tin oxide, another oxide, a non-metal material, or another material. In some embodiments, the second layer of material 304 includes titanium, indium tin oxide, chromium, silicon nitride, silicon oxide, or silicon oxynitride, a non-metal material, or another material. As shown in FIG. 3, the first and second layers of material 302, 304 fill the first and second recesses 202-1, 202-2. In various embodiments, the first portion 204-1 of the pixel define layer 108 is disposed between the first anode 106-1 and the first layer of material 302. In one or more embodiments, the second portion 204-2 of the pixel define layer 108 is disposed between the second anode 106-2 and the first layer of material 302.

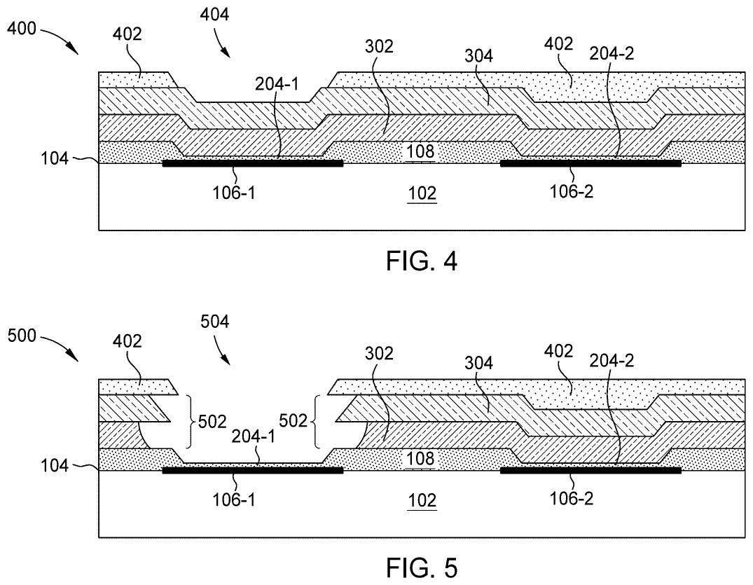

FIG. 4 is a schematic cross-sectional view 400 of masking a first region of the first layer of material 302 and second layer of material 304 using a photosensitive material 402 with an opening 404 formed over a first portion of the first layer of material 302 and the second layer of material 304. In some embodiments, the photosensitive material 402 (e.g., a mask layer) includes an organic material that is not etched in an etching process. In one or more embodiments, the photosensitive material 402 includes a photoresist material (e.g., a photoresist mask) which can be positive or negative and that is coated onto the second layer of material 304. In various embodiments, the opening 404 is formed by a lithographic pattering process that includes an exposure and develop step.

FIG. 5 is a schematic cross-sectional view 500 of removing a first portion of a first layer of material 302 and a first portion of a second layer of material 304 to expose a first portion 204-1 of a pixel define layer 108 and form a first overhang portion 502 over an extended first recess 504 in the pixel define layer 108. In one or more embodiments, an etching process is performed on the first and second layers of material 302, 304 using the photosensitive material 402 with the opening 404. In some embodiments, the etching process removes portions of the first and second layers of material 302, 304 exposed by the opening 404 but the etching process does not damage the first anode 106-1 which is covered by the first portion 204-1 of the pixel define layer 108. In some embodiments, the etching process includes a multistep process that includes exposing the second layer of material 304 to a dry etching process (e.g., a plasma enhanced etching process) for a first period of time and then exposing the exposed first layer of material 302 to a wet etching process (e.g., an acid-based etching process) or a wet and dry etching process for a second period of time, wherein rinsing steps may be performed between the exposures. Notably, without the first portion 204-1, the first anode 106-1 would likely be damaged by the etching process.

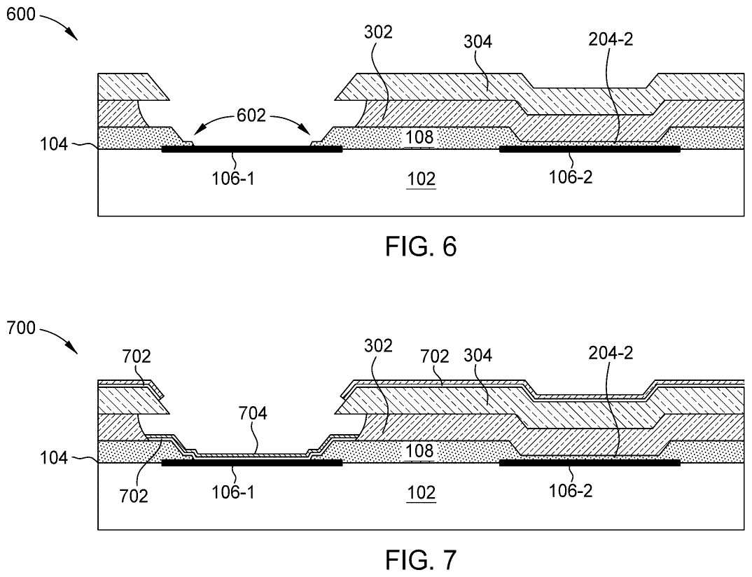

FIG. 6 is a schematic cross-sectional view 600 of removing a first portion 204-1 of a pixel define layer 108 using a first overhang portion 502 as a mask to expose at least a portion of a first anode region. In various embodiments, exposing the portion of the first anode region exposes a portion of the first anode 106-1. As shown, the photosensitive material 402 has also been removed. In one or more embodiments, the pixel define layer 108 includes a profile 602 (e.g., a 2-step profile, a stepwise profile, a curved profile, a convex profile, a concave profile, or another profile) after removing the first portion 204-1 of the pixel define layer 108. As shown, the profile 602 includes a first step formed by forming the first recess 202-1 and a second step formed by removing the first portion 204-1 of the pixel define layer 108.

FIG. 7 is a schematic cross-sectional view 700 of emissive layer material 702 deposited over a portion of a first anode 106-1 and one or more of the layers of material 302, 304. In various embodiments, the emissive layer material 702 includes organic light emitting diode (OLED) material (e.g., organic material). The emissive layer material 702 emits light (photons) in response to an electric current passing through the emissive layer material 702 due to recombination of electrons and holes within organic molecules included in the emissive layer material 702. In some embodiments, the first overhang portion 502 separates emissive layer material 702 covering the portion of the first anode 106-1 and the stepwise profile 602 of the pixel define layer 108 from emissive layer material 702 covering the second layer of material 304. A cathode 704 is deposited over the emissive layer material 702.

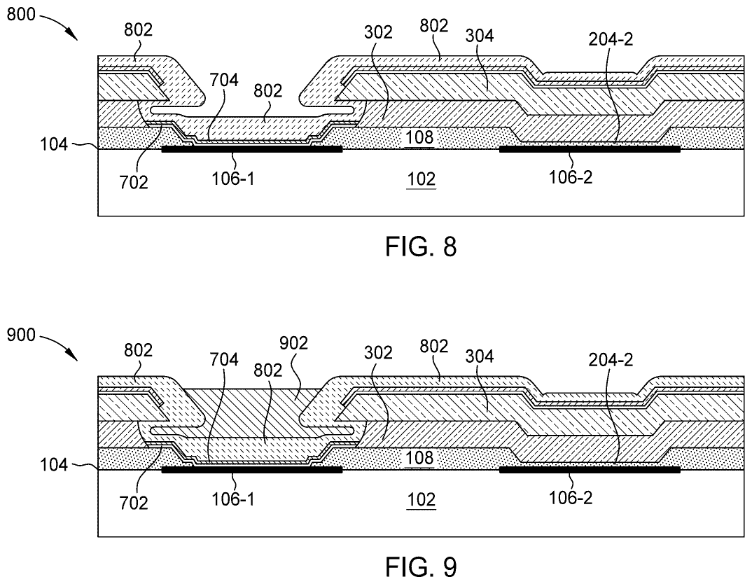

FIG. 8 is a schematic cross-sectional view 800 of thin-film encapsulation material 802 deposited over emissive layer material 702. In various embodiments, the thin-film encapsulation material 802 includes non-conductive inorganic material such as silicon-containing material. The silicon-containing material may include Si₃N₄ containing materials. In some embodiments, the thin-film encapsulation material 802 includes dielectric material. The thin-film encapsulation material 802 has a thickness in a range of about 0.01 micrometers (μm) to about 3 μm such as about 0.5 μm.

FIG. 9 is a schematic cross-sectional view 900 of masking a first overhang portion 502. As shown, a photoresist material 902 is disposed over the first overhang portion 502. In some embodiments, the photoresist material 902 is also disposed over a portion of the thin-film encapsulation material 802 which is disposed below the first overhang portion 502 and above the portion of the first anode 106-1.

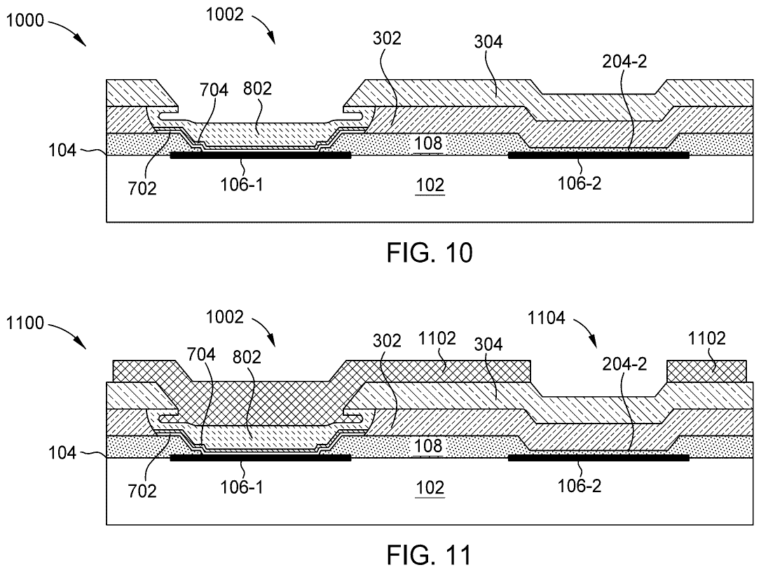

FIG. 10 is a schematic cross-sectional view 1000 of removed thin-film encapsulation material 802 and emissive layer material 702. As shown, the thin-film encapsulation material 802 and the emissive layer material 702 covered by the photoresist material 902 remain in a pixel 1002. For example, the thin-film encapsulation material 802 is removed using a dry etching process and the emissive layer material 702 that is not covered by the photoresist material 902 is removed using a wet etching process or a wet and dry etching process. After removing the thin-film encapsulation material 802 and the emissive layer material 702 that is not covered by the photoresist material 902, the photoresist material 902 is removed/stripped by solvents/chemicals to expose the pixel 1002.

FIG. 11 is a schematic cross-sectional view 1100 of masking a first layer of material 302 and a second layer of material 304 using a photoresist 1102 with an opening 1104 over a second portion of the first layer of material 302 and a second portion of the second layer of material 304. As shown, the photoresist 1102 covers the pixel 1002 and the opening 1104 exposes the second portions of the first and second layers of material 302, 304 that are disposed in the second recess 202-2 and above the second anode region and the portion of the second anode 106-2.

In various embodiments, a second pixel can be fabricated using the portion of the second anode 106-2 in a same or similar manner as described for the pixel 1002 with respect to FIGS. 4-10. In one or more embodiments, the second portion 204-2 of the pixel define layer 108 prevents the second anode 106-2 from being damaged during an etching process, and the second portion 204-2 can be removed by using a second overhang portion formed below the opening 1104.

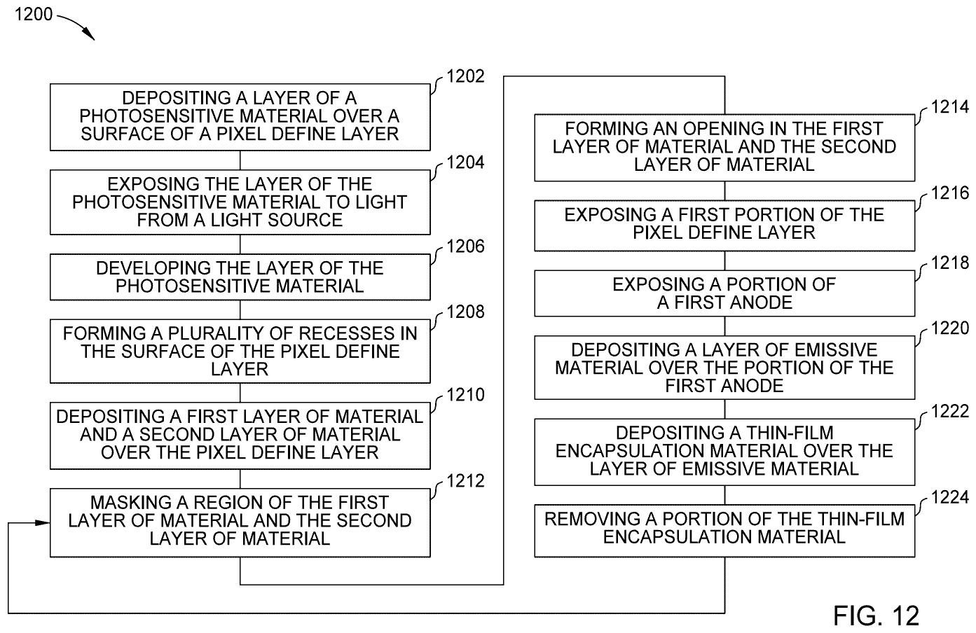

FIG. 12 is a process flow diagram illustrating a method 1200 forming a portion of an OLED module. At operation 1202, a layer of a photosensitive material is deposited over a surface of a pixel define layer. In some embodiments, the layer 112 of the photosensitive material is deposited over the surface 109 of the pixel define layer 108.

At operation 1204, the layer of the photosensitive material is exposed to light from a light source. In one or more embodiments, the layer 112 of the photosensitive material is exposed to light from the light source.

At operation 1206, the layer of the photosensitive material is developed. In various embodiments, the layer 112 of the photosensitive material is developed using a developer.

At operation 1208, a plurality of recesses are formed in the surface of the pixel define layer. In certain embodiments, the first recess 202-1 and the second recess 202-2 are formed in the surface 109 of the pixel define layer 108.

At operation 1210, a first layer of material and a second layer of material are deposited over the pixel define layer. In some embodiments, the first layer of material 302 is deposited over the pixel define layer 108 and the second layer of material 304 is deposited over the first layer of material 302.

At operation 1212, a region of the first layer of material and the second layer of material is masked. In one or more embodiments, the region of the first layer of material 302 and the second layer of material 304 is masked.

At operation 1214, an opening is formed in the first layer of material and the second layer of material. In various embodiments, the extended first recess 504 is formed into the pixel define layer 108.

At operation 1216, a first portion of the pixel define layer is exposed. In certain embodiments, the first portion 204-1 of the pixel define layer 108 is exposed.

At operation 1218, a portion of a first anode is exposed. In some embodiments, the portion of the first anode 106-1 is exposed.

At operation 1220, a layer of emissive material is deposited over the portion of the first anode. In one or more embodiments, the emissive layer material 702 is deposited over the portion of the first anode 106-1.

At operation 1222, a layer of thin-film encapsulation material is deposited over the layer of emissive material. In various embodiments, the thin-film encapsulation material 802 is deposited over the emissive layer material 702.

At operation 1224, a portion of the thin-film encapsulation material is removed. In certain embodiments, the thin-film encapsulation material 802 and the emissive layer material 702 that is not covered by the photoresist material 902 are removed. In some embodiments, one or more of the operations 1212, 1214, 1216, 1218, 1220, 1222 are repeated once with respect to the second anode 106-2 and one or more of the operations 1212, 1214, 1216, 1218, 1220, 1222 are repeated again with respect to a third anode 106-3.

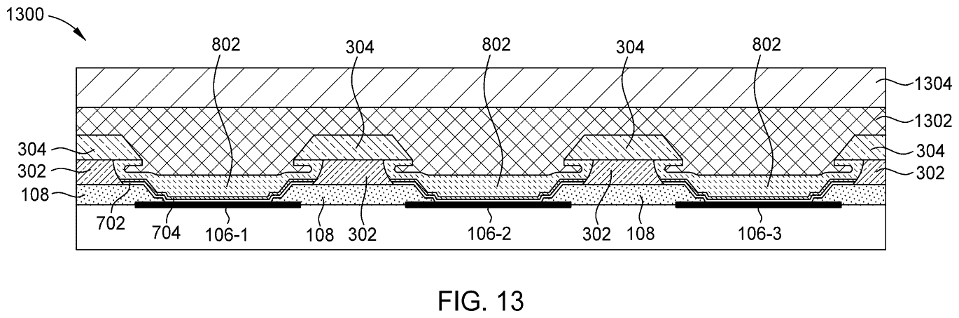

FIG. 13 is a schematic cross-sectional view 1300 of an OLED device assembly that can be formed by performing one or more of operations 1212, 1214, 1216, 1218, 1220, 1222, 1224 at least three times, wherein, in some embodiments, the composition of the emissive material deposited during operation 1220 during each successive repetition of the sequence of operations is different. As shown in the OLED device assembly, the first anode 106-1 corresponds to a first pixel (e.g., a red pixel), the second anode 106-2 corresponds to a second pixel (e.g., a green pixel), and the third anode 106-3 corresponds to a third pixel (e.g., a blue pixel). In one or more embodiments, one or more monomer layers 1302 are disposed on or over the thin-film encapsulation material 802 and the second layer of material 304. In one or more embodiments, a global encapsulation layer 1304 is disposed on or over the one or more monomer layers 1302.

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or processes described with respect to one implementation may be combined with the features, components, and/or processes described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more operations or actions for achieving the described method. The method operations and/or actions may be interchanged with one another without departing from the scope of the claims. In other words, unless a specific order of operations or actions is specified, the order and/or use of specific operations and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. A method, comprising:
forming a plurality of recesses in a pixel define layer formed over a surface of a substrate, wherein the plurality of recesses in the pixel define layer are each disposed over an anode region formed in the surface of the substrate;
depositing a blanket layer of material over the pixel define layer;
removing a first portion of the blanket layer of material disposed over a first recess of the plurality of recesses to expose a first portion of the pixel define layer and form a first overhang portion above the first recess; and
removing the first portion of the pixel define layer using the first overhang portion as a mask to expose at least a portion of a first anode region.

2. The method of claim 1, further comprising masking the blanket layer of material using a mask with an opening over the first portion of the blanket layer of material.

3. The method of claim 1, wherein the blanket layer of material includes a first layer of material and a second layer of material.

4. The method of claim 3, wherein the first layer of material includes at least one of aluminum, molybdenum, copper, indium zinc oxide, indium tin oxide, or another oxide.

5. The method of claim 3, wherein the second layer of material includes at least one of titanium, indium tin oxide, indium zinc oxide, chromium, silicon nitride, silicon oxide, or silicon oxynitride.

6. The method of claim 1, further comprising:
removing a second portion of the blanket layer of material disposed over a second recess of the plurality of recesses to expose a second portion of the pixel define layer and form a second overhang portion above the second recess; and
removing the second portion of the pixel define layer using the second overhang portion as a mask to expose at least a portion of a second anode region.

7. The method of claim 1, wherein the plurality of recesses in the pixel define layer are formed using a halftone mask.

8. The method of claim 7, wherein the halftone mask includes a halftone phase shift mask.

9. The method of claim 1, wherein removing the first portion of the blanket layer of material includes an etching process and the first portion of the pixel define layer is configured to mask the first anode region from the etching process.

10. The method of claim 1, further comprising:
depositing a first emissive layer material over the portion of the first anode region;
removing a second portion of the blanket layer of material disposed over a second recess of the plurality of recesses to expose a second portion of the pixel define layer and form a second overhang portion above the second recess;
removing the second portion of the pixel define layer using the second overhang portion as a mask to expose at least a portion of a second anode region; and
depositing a second emissive layer material over the portion of the second anode region.

11. A method, comprising:
forming a plurality of recesses in a pixel define layer formed over a surface of a substrate, wherein the plurality of recesses in the pixel define layer are each disposed over an anode region formed in the surface of the substrate;
depositing a first layer of material over the pixel define layer;
depositing a second layer of material over the first layer of material;
removing a first portion of the first layer of material disposed over a first recess of the plurality of recesses and a first portion of the second layer of material disposed over the first recess to expose a first portion of the pixel define layer and form a first overhang portion above the first recess; and
removing the first portion of the pixel define layer using the first overhang portion as a mask to expose at least a portion of a first anode region.

12. The method of claim 11, wherein removing the first portion of the first layer of material and the first portion of the second layer of material includes an etching process and the first portion of the pixel define layer is configured to mask the first anode region from the etching process.

13. The method of claim 11, wherein the first layer of material includes at least one of aluminum, molybdenum, copper, indium zinc oxide, indium tin oxide, or another oxide.

14. The method of claim 11, wherein the second layer of material includes at least one of titanium, indium tin oxide, indium zinc oxide, chromium, silicon nitride, silicon oxide, or silicon oxynitride.

15. The method of claim 11, wherein removing the first portion of the pixel define layer forms a profile in the pixel define layer.

16. The method of claim 11, wherein the plurality of recesses in the pixel define layer are formed using a halftone mask.

17. The method of claim 11, further comprising depositing a mask layer over the second layer of material having an opening over the first portion of the second layer of material.

18. The method of claim 11, further comprising removing a second portion of the first layer of material disposed over a second recess of the plurality of recesses and a second portion of the second layer of material disposed over the second recess to expose a second portion of the pixel define layer and form a second overhang portion above the second recess.

19. The method of claim 18, further comprising removing the second portion of the pixel define layer using the second overhang portion as a mask to expose at least a portion of a second anode region.

20. A device subassembly, comprising:
a substrate comprising a surface;
a plurality of anode regions disposed on the surface of the substrate;
a pixel define layer disposed over the surface of the substrate having a profile comprising a first step and a second step;
a plurality of openings in the pixel define layer, wherein each opening of the openings in the pixel define layer is formed over an anode region of the anode regions; and
a first layer of material and a second layer of material disposed over the pixel define layer, wherein:
openings are formed in the first layer of material and the second layer of material, and
the openings in the first layer of material and the second layer of material are formed over and surround the openings in the pixel define layer.
